(19) United States
(12) Patent Application Publication
(10) Pub. No.: US 2021/0249218 A1
(43) Pub. Date: Aug. 12, 2021

(54) MULTIPOLE LENS, ABERRATION CORRECTOR USING SAME, AND CHARGED PARTICLE BEAM DEVICE

(71) Applicant: HITACHI HIGH-TECH CORPORATION, Tokyo (JP)

(72) Inventors: Tomonori NAKANO, Tokyo (JP); Yu YAMAZAWA, Tokyo (JP)

(73) Assignee: HITACHI HIGH-TECH CORPORATION, Tokyo (JP)

(21) Appl. No.: 17/049,364

(22) PCT Filed: May 10, 2018
(86) PCT No.: PCT/JP2018/018215

§ 371 Date: Oct. 21, 2020

(51) Int. Cl. H01J 37/141; H01J 37/153; H01J 37/28

(52) U.S. Cl. CPC H01J 37/141; H01J 37/153; H01J 2237/1405; H01J 2237/1534; H01J 37/28

(57) ABSTRACT

Provided is a winding type aberration corrector that generates a multipole field, in which mechanical positional accuracy required to dispose the current wires can be mitigated. For this purpose, a multipole lens constituting the aberration corrector includes a magnetic core, and a plurality of current wires, in which a plurality of grooves are provided in an inner wall of the magnetic core, centers of the plurality of grooves being disposed axisymmetrically relative to a central axis of the magnetic core, and main wire portions of the plurality of current wires are respectively disposed in the plurality of grooves of the magnetic core.

### TECHNICAL FIELD

The present invention relates to a charged particle beam application technique, and particularly to a charged particle beam device, such as a scanning electron microscope and a transmission electron microscope, that is mounted with an aberration corrector.

### BACKGROUND ART

In order to improve resolution, an aberration corrector is guided into a charged particle beam device such as a scanning electron microscope (SEM) and a scanning transmission electron microscope (STEM). A type of the aberration corrector includes multipole lenses provided in multiple stages. The multipole lenses combine a plurality of multipole fields by generating an electric field or a magnetic field, and remove an aberration included in a charged particle beam passing through an inside of the multipole lenses. PTL 1 discloses a winding type aberration corrector that generates a multipole field using a magnetic field from a plurality of current wires.

PTL 2 discloses that an in-lens deflector is provided in an objective lens in order to reduce deflection coma aberration, and discloses an example of using a toroidal deflector in which toroidal coils are wound around a ring-shaped ferrite core as the in-lens deflector.

### CITATION LIST

### Patent Literature

PTL 1: JP-A-2009-54581

PTL 2: JP-A-2013-229104

### SUMMARY OF INVENTION

### Technical Problem

In PTL 1, although an aberration corrector of a relatively inexpensive multipole correction system can be achieved by forming a multipole field by using current wires, high mechanical positional accuracy, in this case, high positional accuracy is required for disposing the current wires.

PTL 2 discloses a deflector using a toroidal coil, but does not constitute a multipole lens for generating a multipole field.

### Solution to Problem

In one embodiment, the multipole lens includes a magnetic core, and a plurality of current wires, in which a plurality of grooves are provided in an inner wall of the magnetic core, centers of the plurality of grooves being disposed axisymmetrically relative to a central axis of the magnetic core, and main wire portions of the plurality of current wires are respectively disposed in the plurality of grooves of the magnetic core. Such multipole lens is used to form an aberration corrector and a charged particle beam device.

### Advantageous Effect

In a winding type aberration corrector that generates a multipole field, mechanical positional accuracy required to dispose the current wires can be mitigated.

Other technical problems and novel characteristics will be apparent from a description of the description and the accompanying drawings.

### BRIEF DESCRIPTION OF DRAWINGS

FIG. 1A is a bird's eye cross-sectional view (schematic view) of a multipole lens.

FIG. 1B is a top view (schematic view) of the multipole lens.

FIG. 1C is a bird's eye view (schematic view) of center positions of grooves provided in a magnetic core.

FIG. 2 is a bird's eye view (schematic view) of current wires.

FIG. 3 is a diagram showing a relation between a position of each current wire (main wire portion) and an intensity of an excited hexapole field.

FIG. 4 is a diagram showing a relation between a width of each groove of the magnetic core and the intensity of the excited hexapole field.

FIG. 5 is a diagram showing a relation between an inner diameter of the magnetic core and the intensity of the excited hexapole field.

FIG. 6 is a diagram showing a relation between the number of windings of each current wire and the intensity of the excited hexapole field.

FIG. 7 is an example of a shape of each groove provided in the magnetic core.

FIGS. 8A through 8E are examples of the shape of the groove provided in the magnetic core.

FIG. 9 is a diagram showing the intensity of the hexapole field excited by the current wires (connection portion).

FIG. 10 is an example of a multipole lens in which a non-magnetic spacer is provided on the magnetic core.

FIG. 11A is a bird's eye cross-sectional view of a magnetic core.

FIG. 11B is a cross-sectional view (plane A0) of the magnetic core.

FIG. 11C is a cross-sectional view (plane A1) of the magnetic core.

FIG. 11D is a cross-sectional view (plane B) of the magnetic core.

FIG. 12 is a diagram illustrating an effect of a multipole lens using the magnetic core provided with upper and lower lids.

FIG. 13A is a diagram showing a magnetic core provided with electrodes.

FIG. 13B is a diagram showing the magnetic core provided with electrodes.

FIG. 14 is a schematic view showing a configuration example of an entire scanning electron microscope incorporated with an aberration corrector.

### DESCRIPTION OF EMBODIMENTS

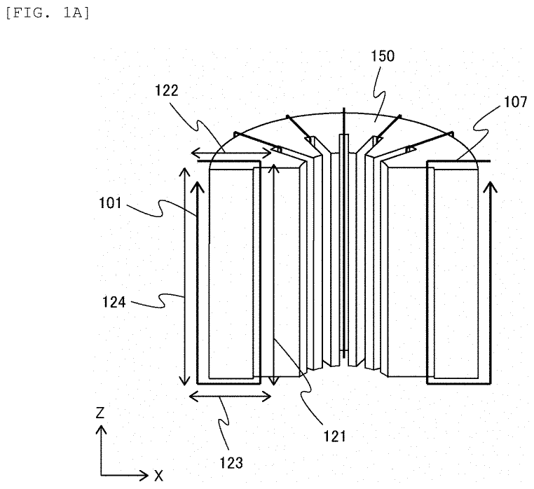

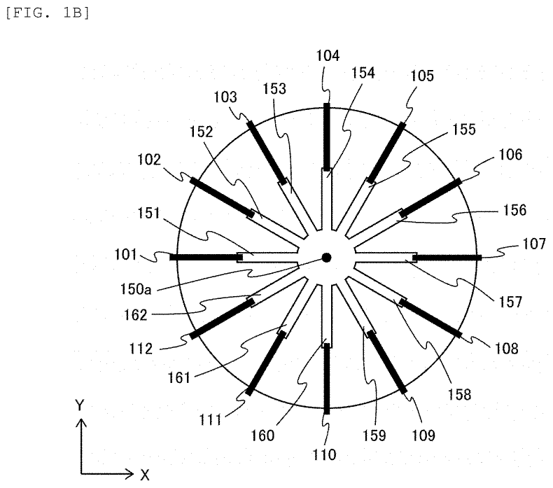

An aberration corrector includes multistage multipole lenses. Each multipole lens of the embodiment has a configuration in which current wires are respectively disposed in grooves provided in an inner wall of a magnetic core. FIG. 1A is a bird's eye cross-sectional view (schematic view) of a one stage multipole lens in a winding aberration corrector, FIG. 1B is a top view (schematic view) of the one stage multipole lens of the winding aberration corrector, and FIG. 1C is a bird's eye view (schematic view) of center positions of grooves provided in the magnetic core. A magnetic core 150 is made of a magnetic material such as pure iron or permalloy, has a cylindrical shape, and has grooves 151 to 162 extending in a Z direction on the inner wall thereof. As shown in FIG. 1C, center positions 151a to 162a of the grooves are provided axisymmetrically relative to a central axis 150a of the magnetic core 150. That is, the center position 151a of the groove 151 and the center position 157a of the groove 157 are disposed in a manner of being axisymmetrical on the same plane relative to the central axis 150a. The center position 152a of the groove and the center position 158a of the groove, the center position 153a of the groove and the center position 159a of the groove, the center position 154a of the groove and the center position 160a of the groove, the center position 155a of the groove and the center position 161a of the groove, and the center position 156a of the groove and the center position 162a of the groove are also in a similar manner, respectively. Although twelve grooves are provided in the example, the number of grooves is not limited. If the number of grooves is k, an angle between adjacent grooves is an angle (360°/k) obtained by dividing by the number k of grooves with the central axis 150a of the magnetic core 150 as a rotation axis.

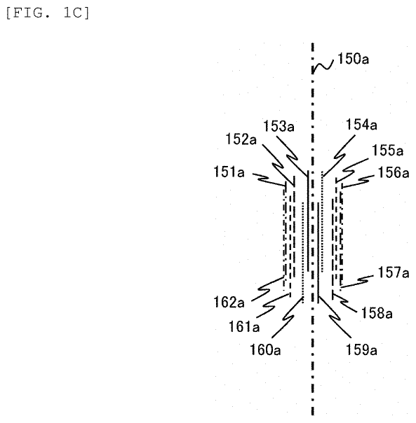

Main wire portions of the current wires 101 to 112 are respectively disposed in the grooves 151 to 162 provided in the magnetic core 150. FIG. 2 is a bird's eye view (schematic view) of the current wires with only the current wires 101 to 112 being extracted. The twelve current wires including the current wires 101 to 112 are disposed around an optical axis 100 of a charged particle beam. The optical axis 100 of the charged particle beam coincides with the central axis 150a of the magnetic core 150.

A structure of each current wire will be described using the current wire 101 shown in FIG. 1A as an example. The current wire 101 has a rectangular circuit shape, and a current is supplied from a power supply (not shown). An arrow attached to the current wire is a direction of the flowing current. Hereinafter, as shown in FIG. 1A, the current wire is divided into four sections corresponding to sides of the rectangular shape, which are respectively referred to as a main wire portion 121, a connection portion 122, a connection portion 123, and a return wire portion 124. The main wire portion 121 refers to a part of the current wire that is disposed in the groove of the magnetic core, and the connection portions 122 and 123 refer to parts by which the main wire portion 121 is guided into the groove from an outside of the magnetic core, or by which the main wire portion 121 is guided to the outside of the magnetic core from the groove, and the return wire portion 124 refers to a part of the current wire that is disposed in the outside part of the magnetic core.

A multipole field is formed by a magnetic field from the main wire portion. Although the power supply is not shown in the winding lens (multipole lens) shown in FIG. 2, it is necessary to cause a current to flow at a specific distribution for the excitation of the multipole field. For example, as a combination for exciting a 2N pole field (N is an integer of 1 or more), if currents applied to the current wires 101 to 112 are set to I1 to I12, respectively, a combination of the current values obtained by (Formula 1) with respect to the reference current AN is taken.

[Formula 1]

Iᵢ=A_{N}·Cos(N(i−1)π/6) (Formula 1)

(Formula 1) shows a current distribution that excites a single multipole field. On the other hand, a plurality of different multipole fields can be superimposed, and in this case, the current wires 101 to 112 are connected to different power supplies.

In a conventional winding lens having no magnetic core, since directions of currents are reversed between the main wire portion and the return wire portion, a multipole field generated by the return wire portion has an effect of weakening a multipole field generated by the main wire portion. On the other hand, in the winding lens of the present embodiment, the magnetic core 150 is disposed between the main wire portion 121 and the return wire portion 124, thereby serving as a magnetic shield, and the return wire portion does not affect the multipole field generated by the main wire portion. Further, the inventors found that the multipole lens of the present embodiment has excellent characteristics for constituting an aberration corrector.

FIG. 3 is obtained by exciting a hexapole field in the multipole lens according to the embodiment while gradually changing a position of each current wire in a radial direction of the magnetic core, and studying a relation between the position of the current wire and the intensity of the hexapole field (shown in a normalized manner). A shape of the magnetic core other than a disposing position of the current wire is the same. As shown in the figure, the larger the current wire position (horizontal axis) is, the more the main wire portion of the current wire is deviated from a side of an inner diameter toward a side of an outer diameter of the magnetic core. From the result, it can be seen that, as in a case where the current wire position is 3 mm to 3.1 mm, there is a region in which the intensity of the excited hexapole field is substantially unaffected even if the main wire portion of the current wire deviates in the radial direction of the magnetic core.

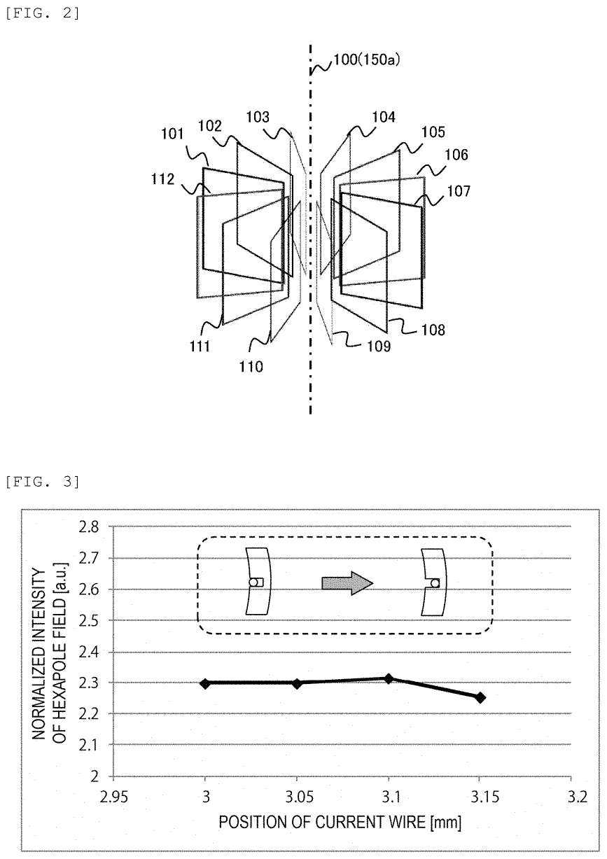

FIG. 4 is obtained by exciting a hexapole field in the multipole lens according to the embodiment using the magnetic core while gradually changing a width W of each groove, and studying a relation between the width W of the groove and the intensity of the hexapole field (shown in a normalized manner). A shape of the magnetic core other than the width of the groove is the same including the disposing position of the current wire. From the result, it can be seen that, as in the case where the groove width is 0.3 mm to 0.5 mm, there is a region in which the intensity of the excited hexapole field is substantially unaffected even if the width of the groove changes.

From the results, it can be seen that the magnetic field intensity excited by the multipole lens according to the present embodiment can be substantially unaffected by the positional accuracy of the main wire portion of the current wire disposed in the groove of the magnetic core. In a conventional winding aberration corrector without using a magnetic core, high accuracy is required for the disposing position of the current wire in order to generate a desired magnetic field. On the other hand, in the winding aberration corrector according to the present embodiment, if the center position of the groove of the magnetic core is highly accurately manufactured in a circumferential direction and the radial direction, deviations of disposing positions of the current wires in the grooves hardly affect the magnetic field intensity generated by the multipole lens, which is actually very advantageous when manufacturing the multipole lens and constituting the aberration corrector.

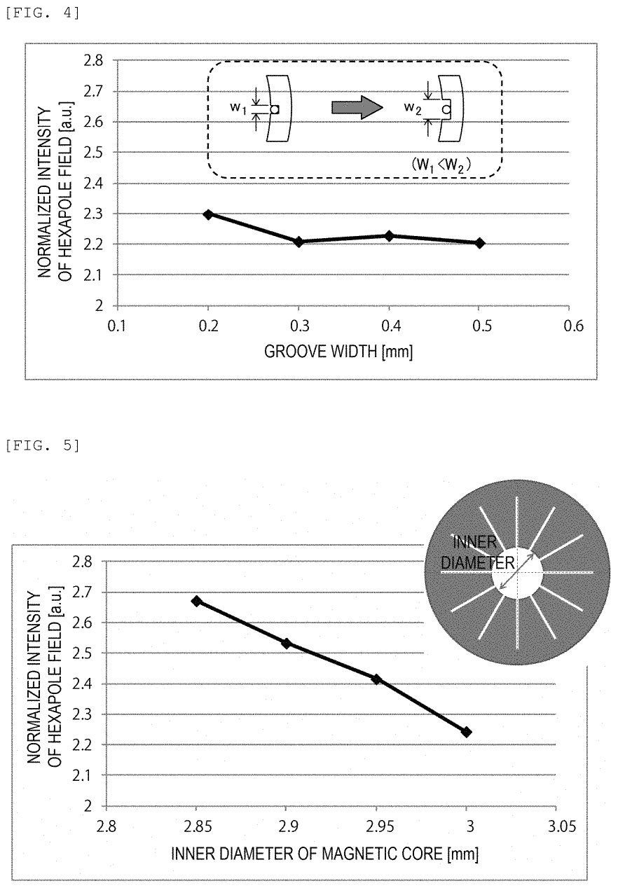

On the other hand, a multipole field intensity generated by the multipole lens can be adjusted by the inner diameter of the magnetic core and the number of windings of the current wire. FIG. 5 is obtained by exciting a hexapole field in the multipole lens according to the embodiment using the magnetic core while gradually changing the inner diameter, and studying a relation between an inner diameter and the intensity of the hexapole field (shown in a normalized manner). Accordingly, it can be seen that the smaller the inner diameter is, the larger the magnetic field intensity excited by the multipole lens is. FIG. 6 is obtained by exciting a hexapole field in the multipole lens according to the embodiment while changing the number of the windings of each current wire, and studying a relation between the number of the windings and the intensity of the hexapole field (shown in a normalized manner). Accordingly, it can be seen that, the larger the number of windings is, that is, the larger a multiplex number of the main wire portion of the current wire disposed in the groove of the magnetic core is, the larger the magnetic field intensity excited by the multipole lens is.

Accordingly, the multipole lens according to the present embodiment is only required such that the inner diameter of the magnetic core and the center position of the groove in which the current wire is arranged are manufactured precisely (for example, within 1 degree with respect to a positional deviation in the circumferential direction), and such that the center positions of the grooves facing each other are disposed axisymmetrically relative to the central axis of the magnetic core, and thus a shape of the groove can be determined in consideration of easiness of winding. FIG. 7 shows an example of the shape of the groove provided in the magnetic core. In the example, the groove 200 is provided with a taper portion 201 expanding toward an inner wall and an inner chamber 202 in which the current wire is disposed.

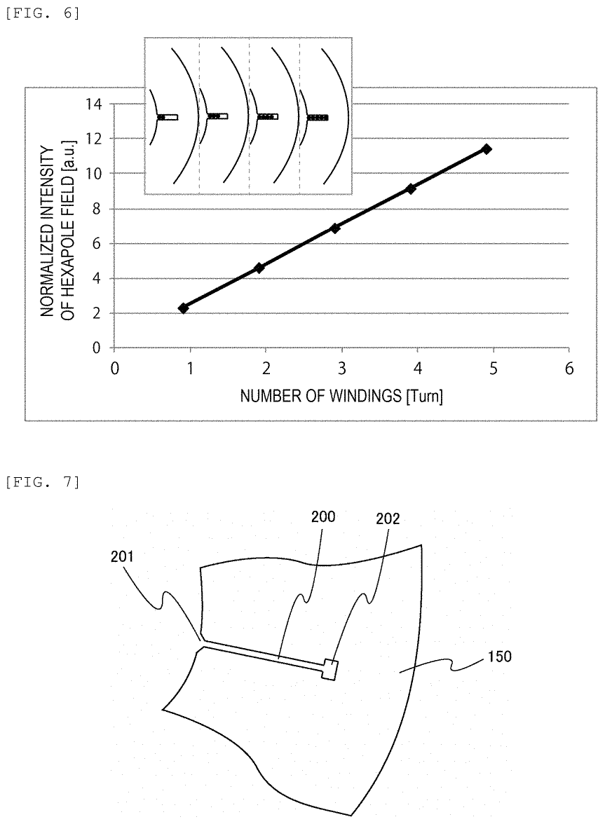

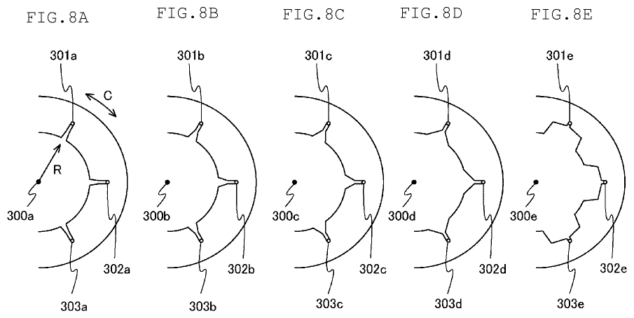

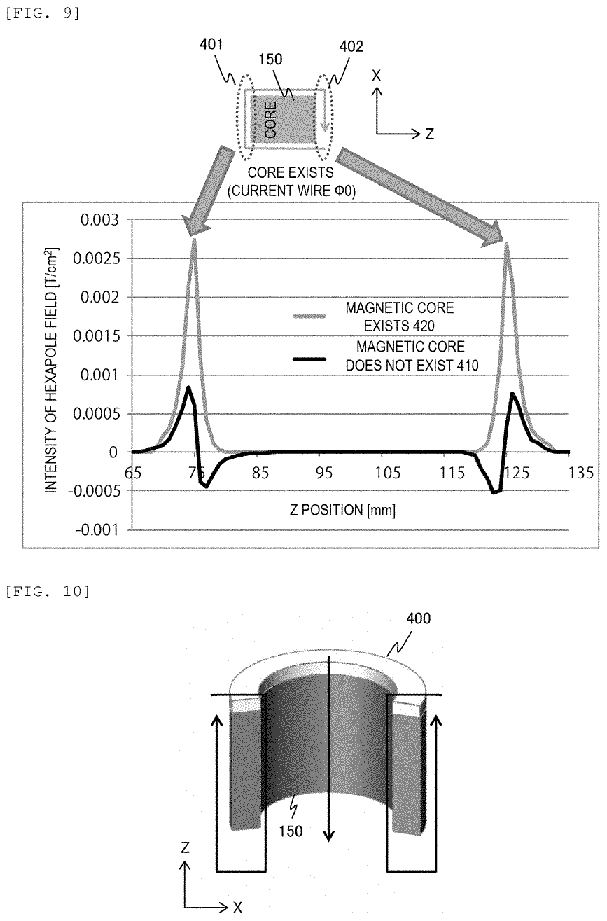

FIG. 8 shows modifications of the grooves provided in the magnetic core. In FIG. 8A to FIG. 8E, center positions 301a to 301e of first grooves, center positions 302a to 302e of second grooves, and center positions 303a to 303e of third grooves are at the same positions in a circumferential direction C and a radial direction R, respectively, with central axes 300a to 300e as origin points. As exemplified, if a size of expansion of the tapered portion is changed depending on a shape of the groove, there is no problem if a bent portion is provided in the tapered portion as shown in FIG. 8E.

Wiring guides (grooves) for positioning the connection portions of each current wire may be provided on an upper surface and a lower surface of the magnetic core. As shown in FIG. 9, since the connection portions of the current wire are facing each other via the magnetic core 150, the magnetic field intensity generated by the connection portions of the current wire is larger than that in a case without magnetic core. That is, in a case of a winding lens in which the magnetic core 150 does not exist, a hexapole field intensity excited by the connection portions 401 and 402 is a waveform 410, whereas in a case of a winding lens in which the magnetic core 150 exists, a hexapole field intensity excited by the connection portions 401 and 402 is a waveform 420, which is significantly larger than the waveform 410. Therefore, high accuracy of the position of the groove in the Z direction is also necessary. Therefore, when a nonmagnetic spacer is provided in the Z direction relative to the magnetic core 150 and one connection portion of the current wire is disposed on the non-magnetic spacer as shown in FIG. 10, the hexapole field intensity excited by the connection portion can be reduced, and the accuracy required for the position of the groove in the Z direction can be mitigated. Although the non-magnetic spacer is provided on the upper surface of the magnetic core 150 in FIG. 10, non-magnetic spacers may be provided on both the upper and lower surfaces.

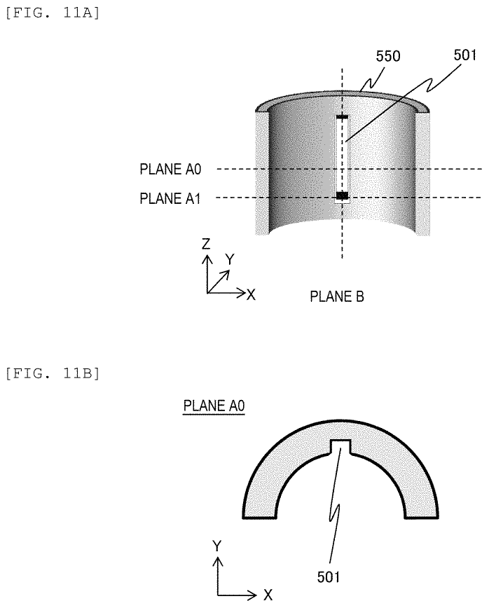

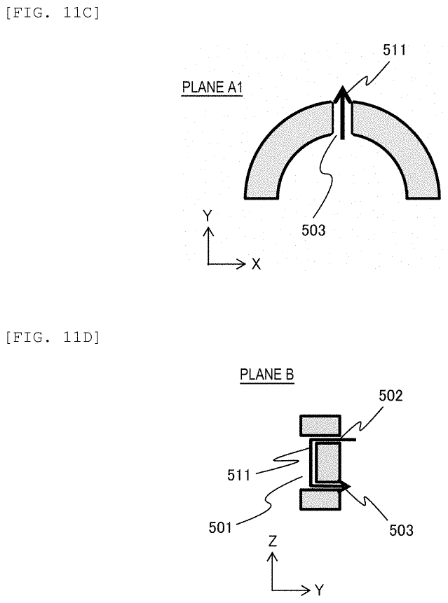

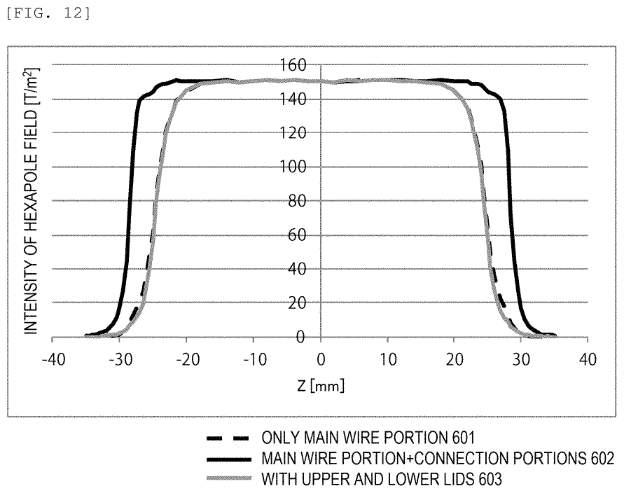

In the above example, the inner wall of the magnetic core is provided with grooves reaching the upper and lower surfaces. On the other hand, the grooves of the magnetic core may be formed into a slit shape. In other words, the magnetic core 150 shown in FIG. 1A corresponds to a shape in which magnetic lids are added above and below the magnetic core 150. The shape of each slit provided in the magnetic core will be described with reference to FIGS. 11A to 11D. FIG. 11A is a bird's eye cross-sectional view of the magnetic core, FIG. 11B is a cross-sectional view of the magnetic core in a plane A0 shown in FIG. 11A, FIG. 11C is a cross-sectional view of the magnetic core in a plane A1 shown in FIG. 11A, and FIG. 11D is a cross-sectional view of the magnetic core in a plane B shown in FIG. 11A. Here, the plane A0 is an XY plane passing near the center of the slit 501 of the magnetic core 550, the plane A1 is an XY plane passing through an end portion of the slit 501, and the plane B is a YZ plane passing through the slit 501. Through holes 502 and 503 are provided at both end portions of the slit 501, and as shown in FIGS. 11C and 11D, a current wire 511 is disposed in the slit 501 through the through holes 502 and 503.

An effect of configuring the multipole lens using the magnetic core with the upper and lower lids shown in FIGS. 11A to 11D will be described with reference to FIG. 12. In FIG. 12, a horizontal axis indicates a position in the Z direction with a center of the current wire being set as an origin point, and a vertical axis indicates the intensity of the hexapole field excited by the multipole lens. A waveform 603 is the intensity of the hexapole field excited by the multipole lens using the magnetic core with the upper and lower lids. On the other hand, as comparative examples, the intensity of the hexapole field excited by only the main wire portion of the current wire is shown by a waveform 601, and the intensity of the hexapole field excited by the main wire portion and the connection portions of the current wire is shown by a waveform 602. The waveform 602 corresponds to the intensity of the hexapole field excited by the multipole lens using the magnetic core shown in FIG. 1A. In the waveform 602, an influence of a magnetic field that excites the connection portion of the current wire appears at both end portions, and a deviation from the waveform 601 is generated. On the other hand, in the waveform 603, it can be seen that the influence of the connection portion seen in the waveform 602 is eliminated, and the hexapole field intensity approximately the same as that of the waveform 601 is obtained. Accordingly, the multipole lens using the magnetic core with the upper and lower lids can eliminate an influence of a positional deviation of the connection portion of the current wire and excite an ideal multipole field by the winding lens.

The magnetic core with the upper and lower lids shown in FIGS. 11A to 11D may be provided with a slit structure extending in the Z direction relative to the magnetic core without reaching the upper and lower surface as described above, or may be a magnetic core with the upper and lower lids shown in FIGS. 11A to 11D by arranging cylindrical shaped magnetic lids above and below the magnetic core. The magnetic lids have the same inner diameter and outer diameter with respect to the magnetic core shown in FIG. 1A. In this case, it is necessary to provide through holes for allowing the connection portions of the current wire to pass through surfaces where the magnetic core and the magnetic lids are in contact. In the present embodiment, no matter whether the magnetic core with the upper and lower lids is formed as one part, or formed as a combination of different parts, a part where the main wire portion of the current wire is disposed is referred to as the magnetic core, and a magnetic portion above or below the magnetic core is referred to as a lid or a magnetic lid.

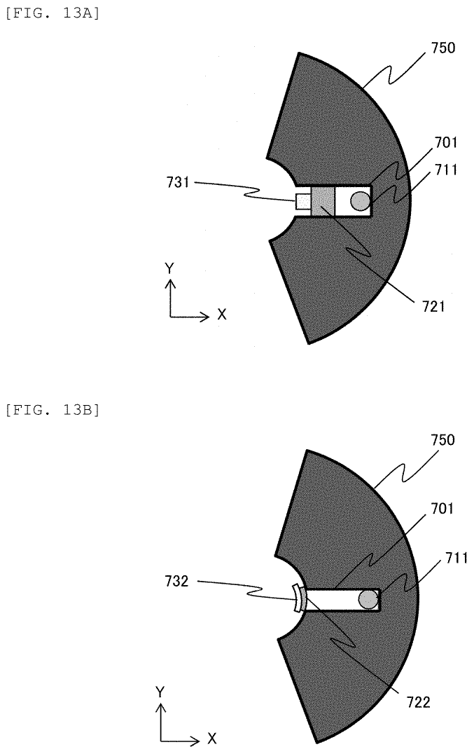

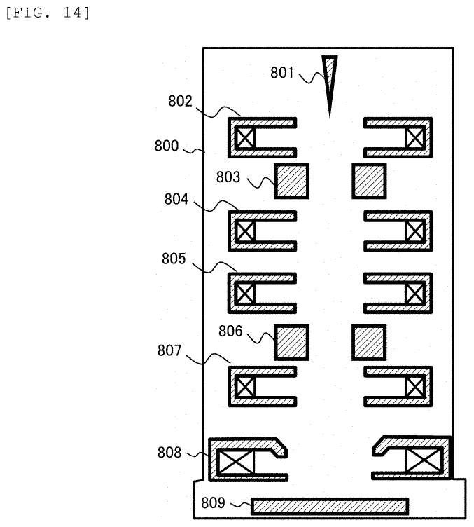

FIGS. 13A and 13B show examples in which electrodes are provided with respect to the magnetic core. The electrodes are used, for example, for generating an electric field for correcting chromatic aberration of a primary electron beam when an aberration corrector using a multipole lens according to the present embodiment is incorporated to form an electron beam device. As described above, a magnetic core 750 is provided with a groove (or slit) 701 in which a current wire 711 is disposed. In an example of FIG. 13A, an electrode 731 is inserted into a groove 701. At the time, since the magnetic core 750 and the electrode 731 have different electric potentials, the electrode 731 is disposed in the groove 701 via an insulator 721. In order to prevent charge-up of the insulator 721, it is desirable that the insulator 721 is not exposed to an optical axis if possible. FIG. 13B is a disposing example in which the insulator cannot be seen from the optical axis. That is, an insulator 722 is provided in the groove 701 along an inner wall of the magnetic core 750, and an electrode 732 is disposed in a manner of covering the insulator 722.

A configuration example of an electron beam device incorporating an aberration corrector using the above-described winding type multipole lens is shown in FIG. 14. In the device, a primary electron beam is emitted from an electron gun 801, formed into parallel beams by a condenser lens 802, and passes through a multipole lens 803. The primary electron beams passed through the multipole lens 803 are transferred to a multipole lens 806 by a condenser lens 804 and a condenser lens 805. After that, the primary electron beams are converged by a condenser lens 807 and an objective lens 808, and irradiated onto a sample 809. An inside of a vacuum vessel 800 is evacuated, and the electron beams travel while the vacuum state is maintained from the electron gun 801 until reaching the sample 809. Each of the multipole lens 803 and the multipole lens 806 is configured with a winding type multipole lens described according to the present embodiment, and a hexapole field is excited in order to perform a spherical aberration correction. The spherical aberration optical system is the same optical system as a general aberration corrector used in the STEM or the like. A difference is that the multipole lenses 803 and 806 are not a multipole formed of a wedge type magnetic material but use the winding type multipole lens as described above. The winding type multipole lens may also be applied to a four stage aberration corrector using a quadrupole field and an octupole field in addition to the aberration corrector using the hexapole field.

The invention is not limited to the above embodiment, and includes various modifications. For example, the above-described embodiment has been described for easy understanding of the invention, and the invention is not necessarily limited to those including all configurations described above. A part of a configuration of one embodiment can be replaced with a configuration of another embodiment, and a configuration of another embodiment can be added to a configuration of one embodiment. A part of the configuration of each embodiment may be added to, deleted from, or replaced with another configuration

### REFERENCE SIGN LIST

100 optical axis
101 to 112, 511, 711 current wire
121 main wire portion
122, 123 connection portion
124 return wire portion
150, 550, 750 magnetic core
151 to 162, 701 groove
400 non-magnetic spacer
501 slit
502, 503 through hole
721, 722 insulator
731, 732 electrode
800 vacuum vessel
801 electron gun
802, 804, 805, 807 condenser lens
803, 806, multipole lens
808, objective lens
809 sample

1. A multipole lens comprising:
a magnetic core; and
a plurality of current wires, wherein
a plurality of grooves are provided in an inner wall of the magnetic core, centers of the plurality of grooves being disposed axisymmetrically relative to a central axis of the magnetic core, and
main wire portions of the plurality of current wires are respectively disposed in the plurality of grooves of the magnetic core.

2. The multipole lens according to claim 1, wherein
each of the plurality of grooves includes a taper portion expanding toward the inner wall, and an inner chamber in which the main wire portion of each current wire is disposed.

3. The multipole lens according to claim 1, wherein
each current wire has a connection portion that guides each main wire portion into each groove from an outside of the magnetic core, or guides the main wire portion from inside the groove to the outside of the magnetic core, and
a non-magnetic spacer is disposed between the connection portions of the current wires and the magnetic core.

4. The multipole lens according to claim 1, wherein
each current wire has a connection portion that guides each main wire portion into each groove from an outside of the magnetic core, or guides the main wire portion from inside the groove to the outside of the magnetic core,
the multipole lens further comprises magnetic lids that are facing each other in a longitudinal direction of the groove of the magnetic core, and
the connection portion of the current wire is disposed in a through hole provided between the magnetic core and one of the magnetic lids.

5. The multipole lens according to claim 1, wherein
each current wire has a return wire portion disposed outside the magnetic core, and
the main wire portion of the current wire is disposed in a multiplexed manner in the groove of the magnetic core.

6. The multipole lens according to claim 1, comprising:
a plurality of electrodes configured to generate an electric field, wherein
the plurality of electrodes are respectively disposed in the plurality of grooves of the magnetic core via insulators.

7. An aberration corrector comprising the multipole lens according to claim 1 in multiple stages.

8. A charged particle beam device comprising:
an electron gun configured to emit a primary electron beam;
an aberration corrector that includes multistage multipole lenses into which the primary electron beam is to be emitted, and
an objective lens into which the primary electron beam that passes through the aberration corrector is to be emitted, wherein
each of the multipole lenses includes a magnetic core and a plurality of current wires, a plurality of grooves are provided in an inner wall of the magnetic core, centers of the plurality of grooves are disposed axisymmetrically relative to a central axis of the magnetic core, and main wire portions of the plurality of current wires are respectively disposed in the plurality of grooves of the magnetic core.

9. The charged particle beam device according to claim 8, wherein
the aberration corrector is an aberration corrector configured to use a hexapole field.

10. The charged particle beam device according to claim 8, comprising:
a plurality of electrodes that are configured to generate an electric field that corrects a chromatic aberration, wherein
the plurality of electrodes are respectively disposed in the plurality of grooves of the magnetic core via insulators.

11. An aberration corrector comprising the multipole lens according to claim 2 in multiple stages.

12. An aberration corrector comprising the multipole lens according to claim 3 in multiple stages.

13. An aberration corrector comprising the multipole lens according to claim 4 in multiple stages.

14. An aberration corrector comprising the multipole lens according to claim 5 in multiple stages.

15. An aberration corrector comprising the multipole lens according to claim 6 in multiple stages.
